(19) United States
(12) Patent Application Publication
(10) Pub. No.: US 2003/0111014 A1
(43) Pub. Date: Jun. 19, 2003

(54) Vaporizer/delivery vessel for volatile/thermally sensitive solid and liquid compounds

(76) Inventors: Matthew B. Donatucci, Bethel, CT (US); Luping Wang, Brookfield, CT (US); James J. Mayer, Fischer, TX (US)

Correspondence Address: INTELLECTUAL PROPERTY / TECHNOLOGY LAW, PO BOX 14329, RESEARCH TRIANGLE PARK, NC, 27709, US

(21) Appl. No.: 10/022,298

(22) Filed: Dec. 18, 2001

(51) Int. Cl. C23C 16/00; B01B 1/00

(52) U.S. Cl. 118/726; 392/386; 392/387; 392/394

(57) ABSTRACT

A vaporizer system for vaporizing solid and/or liquid chemical source materials under uniform heating conditions within the vaporizer system, with reduced condensation of vaporized source materials and minimization of “cold spots” within the vaporizer, to provide a substantially continuous flow of vapor to a downstream implantation or deposition (e.g., MOCVD) system. The vaporizer includes a thermally conductive block having a multiplicity of elongated wells formed therein for holding a vapor source material. Within the thermally conductive block is an interior volume communicating with the elongated wells. The thermally conductive block is sealed to form a closed vessel and heat is applied thereto to evenly heat all the elongated wells simultaneously and vaporize the source material therein.

### BACKGROUND OF THE INVENTION

1. Field of the Invention

The present invention relates to a vaporizer, and more particularly, to a vaporizer and delivery system having multiple elongated wells to provide increased surface area for vaporization of liquids and solid materials, e.g., liquid and solid source reagents used in ion implantation and chemical vapor deposition processes.

2. Description of the Related Art

In the fabrication of integrated circuits, a number of processes have been established that require the application of ion beams onto semiconductor wafers. These processes include ion implantation, ion beam milling and reactive ion etching.

Ion implantation has become a standard accepted technology utilized by the semiconductor industry for impurity doping of workpieces such as silicon wafers that are used in integrated circuits. Conventional ion implantation systems include an ion source in which a dopant element is ionized and then subsequently accelerated to form an ion beam directed at a workpiece surface for implantation. The dopant source material may be supplied as a liquid or a solid, depending on its chemical and physical properties. When a solid dopant material is used, it is generally placed within a vaporizer to be heated and the subsequently formed vapors are transported into the interior of the ion source for ionization.

Typical source materials used for fabrication of integrated circuits include boron (B), phosphorous (P), gallium (Ga), indium (In), antimony (Sb), and arsenic (As). Solid ion source material is greatly preferred for safety reasons, however, solid semiconductor dopants have presented serious technical and operating problems. For instance, utilization of a solid precursor material in vaporizers causes extended down time of the process tool, poor product quality, and deposit buildup within the vaporizer and ion source.

Prior art vaporizer systems have numerous disadvantages, including buildup of condensed material within the vaporizers, and formation of “cold spots” within the interior of the vaporizers due to lack of uniform heating therein. The buildup of unwanted deposits is exacerbated in vaporizer systems that require internal moving surfaces for revolving individual vials and/or wells of source material. These internal mechanisms introduce additional “cold spots” within the vaporizers and provide for further deposition of vaporized material. Additionally, due to the buildup of deposits on internal moving mechanisms, operation of these vaporizers is not efficient or reliable. The shortcomings of the prior art vaporizers are especially noticeable with solid source materials that are temperature-sensitive and have a low vapor pressure. Thus, it is difficult to vaporize a solid at a controlled rate such that a reproducible flow of vaporized solid precursor can be delivered to a downstream deposition system or process tool.

Decaborane is a highly advantageous solid source material for boron doping of semiconductor substrates, since upon ionization the compound can provide a molecular ion containing ten boron atoms. Such a source is especially suited for high dose/low energy implant processes used to create shallow junctions because a molecular decaborane ion beam can implant ten times the boron dose per unit of current as can a monotonic boron ion beam.

However, decaborane has a low vapor pressure and is thermally sensitive, and thus, vaporization has not been fully successful in the prior art vaporizers. Decaborane tends to condense in “cold spots” and thermally decompose within the prior art vaporizers thereby causing a buildup of deposits on internal moving mechanisms and/or a reduced flow of deliverable decaborane vapor to the ion source chamber.

Accordingly, there is need in the art for a vaporizer system that efficiently vaporizes solid and liquid chemical sources without concomitant disadvantages of the prior art, such as thermal disassociation of the source material, inoperability of internal moving parts or surfaces due to deposit buildup within the vaporizer, condensation of low vapor pressure compounds due to “cold spots” within the vaporizer, and/or inconsistent vapor flow to downstream deposition systems.

### SUMMARY OF THE INVENTION

The present invention relates to a vaporizer system and method for vaporizing solid and liquid chemical sources. Such system and method have particular utility for semiconductor manufacturing applications.

The system and method of the invention provide uniform heating within the vaporizer system, reduced condensation of vaporized solid precursors having low vapor pressures, and minimize “cold spots” within the vaporizer, thereby enabling a continuous flow of vapor to a downstream deposition system.

In one aspect, the invention relates to a vaporizer having no internal moving or rotating surfaces, which as a consequence provides uniform heating of source material for vaporization.

In another aspect, the invention relates to a method of vaporizing and delivering a continuous flow of vaporized source material by simultaneously heating a multiplicity of elongated wells to provide an increased amount and flow of vaporized material.

Yet another aspect of the present invention relates to a vaporizer system that provides a continuous flow of vapor to an ion source including a Freeman and Bernas type apparatus.

Still another aspect of the present invention relates to introducing a source material for vaporization without the necessity of using an internal mechanism for mechanically rupturing a source material vial.

In accordance with one aspect of the present invention, there is provided a vaporizer comprising a thermally conductive block having a multiplicity of elongated wells formed therein for placement of a vapor source material. Within the thermally conductive block is an interior void space communicatively connected to the multiplicity of elongated wells. The thermally conductive block is sealed to form a closed vessel and heat is applied thereto to heat the interior void space and elongated wells simultaneously and uniformly to vaporize the source material therein.

The temperature and pressure within the sealed vaporizer are controlled by a temperature regulating device. Vaporized source material accumulates within at least the interior void space for release through an outlet that is communicatively connected to a downstream deposition system. The deposition system may include, without limitation, a plasma doping system, ion implantation system, chemical and metal organic vapor deposition systems, etc.

In one embodiment of the vaporizer system, the elongated wells are of a cylindrical configuration and are provided in a sufficient quantity to provide corresponding additional surface area for contacting source material, to produced correspondingly increased amounts of vaporized source material.

In another aspect, the invention relates to a method for vaporizing a source material comprising the steps of:

introducing a source material into a multiplicity of elongated wells in a thermally conductive block, the multiplicity of elongated wells communicatively connected to an interior space within the thermally conductive block for accumulation of vaporized source material;

sealing the thermally conductive block to form a sealed vaporizer and/or a vacuum within the multiplicity of wells and interior space;

applying heat to the thermally conductive block to heat the elongated wells simultaneously and vaporize the source material therein; and

delivering the vaporized source material to a communicatively connected deposition system.

Other aspects, features and embodiments of the present invention will be more fully apparent from the ensuing disclosure and appended claims.

### BRIEF DESCRIPTION OF THE DRAWINGS

FIG. 1 is side-elevational view of a vaporizer in accordance with one embodiment of the present invention.

FIG. 2 is a top view of a multiplicity of elongated wells formed in a thermally conductive block in accordance with the present invention.

FIG. 3 is a perspective view of the thermally conductive block of FIG. 2.

FIG. 4 is a wiring diagram for heating elements and controlling device in accordance with an illustrative embodiment of the present invention.

### DETAILED DESCRIPTION OF THE INVENTION AND PREFERRED EMBODIMENTS THEREOF

The present invention is based on the observation that certain source materials used in vaporizer systems are not adequately vaporized in sufficient quantities to provide a continuous flow of vapors to a downstream deposition system, due to “cold spots” within the vaporizer that cause condensation of vapors therein.

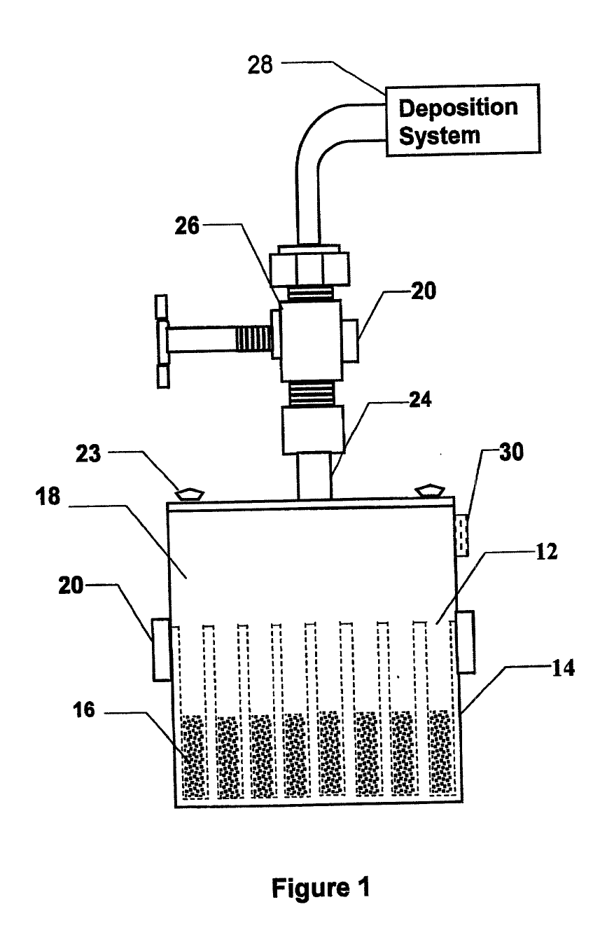

A vaporizer in accordance with one embodiment of the present invention and illustrated in FIG. 1 overcomes the deficiencies of prior art vaporizers. A thermally conductive block 14, fabricated of a suitable heat-conducting material, such as for example silver, silver alloys, copper, copper alloys, aluminum, aluminum alloys, lead, nickel clad, stainless steel, graphite and/or ceramic material, has a multiplicity of elongated wells 12 bored therein. A source material 16 is introduced into the elongated wells for direct contact with interior side walls of the elongated wells.

The thermally conductive block 14 further comprises an interior void space 18 communicatively connected to the elongated wells 12. The conductive block is heated by heating means 20 positioned on the outer surface of the conductive block to supply a sufficient amount of heat to ensure that essentially all of the interior surfaces of the elongated wells are heated substantially simultaneously and uniformly.

The vaporized material flows through conduit 24, through a shut-off valve 26 (in an open position) and into a deposition system 28 wherein the vaporized material may be implanted in or deposited on a receiving substrate. Conduit 24 and shut-off valve 26 are preferably heated to ensure continuous flow of vapors with minimal amount of condensation or deposition of vaporized materials therein. Additionally the delivery system will utilize a heated mass flow or pressure controller to more accurately deliver appropriate process demanded flow rates.

The thermally conductive block 14, defining interior head space 18 and elongated wells 12 therein, is formed of a suitable conductive material, and preferably is fabricated from aluminum or copper because of the high thermal conductivity of these metals. The interior head space 18 is bored out of the block in addition to the borings of the elongated wells. Preferably, the interior volume of the conductive block is in a range of from about 120 cm³ to about 200 cm³, and more preferably is in a range of from about 140 cm³ to about 170 cm³. The internal volume of the conductive block is bifurcated into the interior void space and elongated wells, and preferably the internal volume of the wells is about ⅓ to about ½ of the internal volume of the conductive block. In one illustrative embodiment, the internal volume of the conductive block is about 160 cm³ and the combined internal volume of the elongated wells is about 60 cm³.

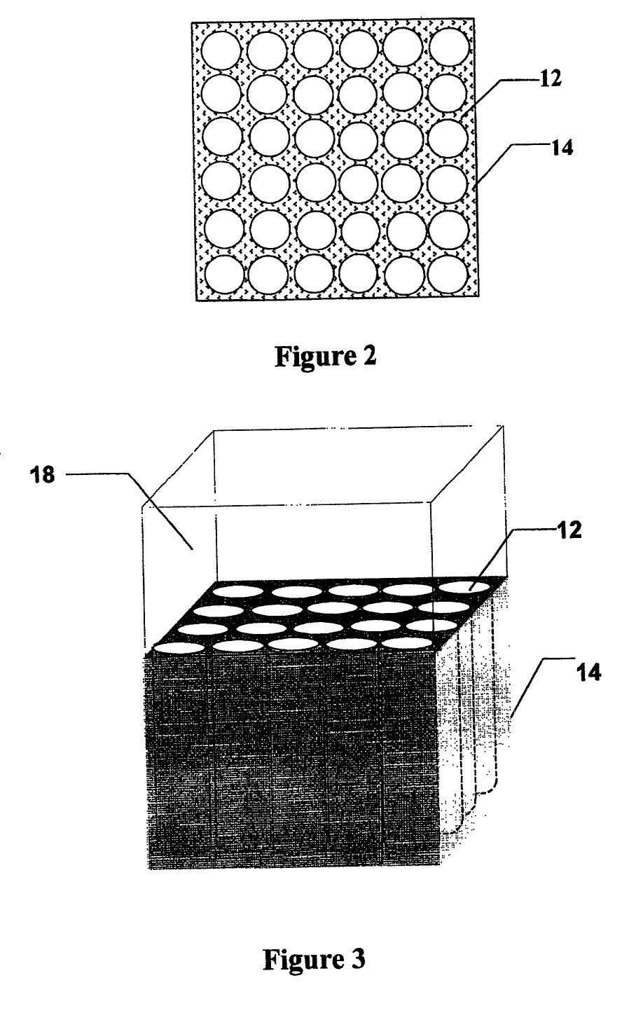

The elongated wells 12 may have any suitable geometric configuration, and preferably have a generally cylindrical configuration as shown in FIGS. 2 and 3. The elongated wells are spaced sufficiently apart in the conductive block to provide an adequate amount of conductive material between the sidewalls of the wells to ensure uniform heating in all the elongated wells. Preferably, the internal diameter of the wells is in a range of from about 3 mm to about 8 mm, and more preferably is in a range of from about 4 mm to about 6 mm. The multiplicity of elongated wells dramatically increases the surface area for contact with the source material, and therefore more source material is vaporized per unit time.

Advantageously, the elongated wells are stationary and not positioned on any moving surface or otherwise translated, thereby providing direct contact of the entire length of each elongated well with the thermally conductive block. Equally important is the reduction (relative to vaporizers of the prior art) of “cold spots” in the vaporizer because the entire interior volume of the vaporizer is heated simultaneously. Reduction of “cold spots” within the vaporizer substantially eliminates deposition or condensation of vapor material while it resides within the vaporizer. Further, the vaporizer of the present invention utilizes a simple design that does not include rotating or injection mechanisms that present problematic deposition surfaces in prior art vaporizers.

The source material 16 is introduced into the elongated wells before sealing the vaporizer with sealing lid 22. The vaporizer system described herein advantageously utilizes solid as well as liquid source materials. Preferably, the source material is a solid including, by way of example, decaborane, solid salts of boron, gallium, indium, antimony, phosphorus arsenic, lithium, sodium tetrafluoroborates, etc., and mixtures thereof.

A solid used as a source material is vaporized through a process of sublimation, effected by heating the walls of the conductive block. The process of sublimation entails the transformation of a solid, e.g., decaborane, from a solid state to a vapor state without entering an intermediate liquid state. The present invention is effective for use with any suitable solid source material, e.g., solid materials characterized by sublimation temperatures in a range of between about 20° C. to about 150° C. and having a vapor pressure in a range of from about 10⁻² Torr to about 10³ Torr.

Temperature is controlled within the vaporizer by any heat regulating system including, without limitation, strip heaters, radiant heaters, circulating fluid heaters, resistant heating systems, inductive heating systems, etc., constructed and arranged for controlled temperature operation.

In one preferred embodiment, at least one resistor 20, and preferably at least four resistors (resistive heating elements), are positioned on the vertical outer surfaces of the conductive block to supply sufficient heat to vaporize the enclosed material and provide a consistent temperature throughout the entire volume of the conductive block.

Further, a resistor may be positioned on shut-off valve 26 to ensure that conduit 24 and the shut-off valve are maintained at a temperature that reduces vapor deposition in the valve or flow line between the vaporizer and the deposition system 28. One skilled in the art will be able to adjust the temperature of the vaporizer to achieve the best results for each specific source material.

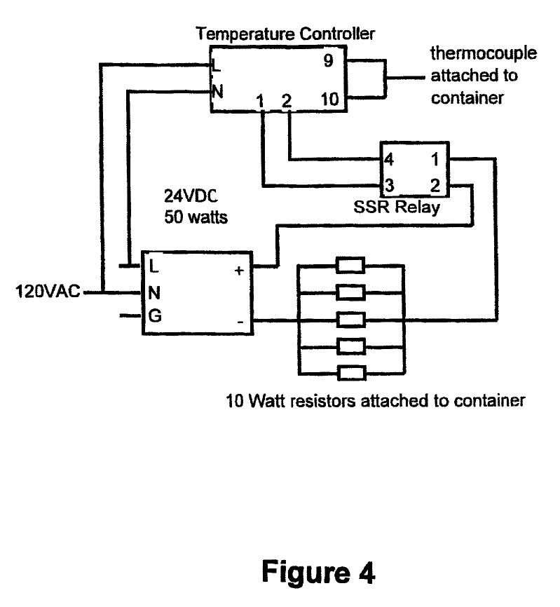

Temperature within the conductive block is sensed by a thermocouple 30 or thermistors, or any other suitable temperature sensing junction or device arranged for contacting a surface of the thermally conductive block. The system therefore may be arranged as shown, including a temperature controlling device that obtains an input temperature from the conductive block via thermocouple 30 and outputs a control signal to resistors 20 so that the conductive block is heated and maintained at a suitable temperature, consistent with the wiring diagram in FIG. 4.

In another embodiment, the conductive block may comprise a window positioned to determine contents within the vaporizer. Suitable materials include transparent materials having a sufficient thermal conductivity to minimize condensation and deposition of vapors on the window including, for example, diamond, sapphire, silicon carbide, transparent ceramic materials, and the like.

The method of utilizing the vaporizer system of the present invention includes introducing a source material 16 into the elongated wells 12 within the thermally conductive block 14. Sealing lid 22 and shut off valve 26, preferably constructed as one piece, are positioned on the top of the conductive block and preferably are sealed thereto, such as by an o-ring element and mechanical fasteners, such as screws 23. Electrical resistors 20 are engaged and the internal temperature is increased to a temperature sufficient to vaporize enclosed source material. Valve 26, having an orifice with a diameter in a range of from about 2 mm to about 10 mm, is opened to deliver vaporized material to the deposition unit 28.

The invention is further illustrated with reference to the following specific, non-example.

### EXAMPLE 1

Decaborane was introduced into a vaporizer constructed in accordance with the present invention. The vaporizer was heated to different temperatures and various orifices sizes were utilized within the shut-off valve to determine optimal sustainable flow rates of decaborane to a downstream deposition or implantation system. The maximum achievable flow rates are set forth in Table 1 (all temperatures listed in the table are vaporizer temperatures):

TABLE 1

| Orifice | | |
|---|---|---|
| Diameter (mm) | Temperature (° C.) | Flow (sccm) |
| 7 | 42 | 0.6 |
| 7 | 52 | 2.8 |
| 7 | 66 | 5.1 |
| 3 | 42 | 0.1 |
| 3 | 52 | 0.8 |
| 3 | 66 | 3.6 |
| 0.004 | 66 | 0.35 |
| 0.055 | 66 | 4.0 |

The foregoing results show that decaborane vaporized in accordance with the teachings of the present invention provided a sustainable and continuous flow as the orifice size was increased. The multiplicity of elongated wells provided an increased surface area for contact with the source material effectively and yielded correspondingly increased amounts of vaporized source material to the downstream deposition or implantation system.

Although the invention has been variously disclosed herein with reference to illustrative embodiments and features, it will be appreciated that the embodiments and features described hereinabove are not intended to limit the invention, and that other variations, modifications and other embodiments will suggest themselves to those of ordinary skill in the art. The invention therefore is to be broadly construed, consistent with the claims hereafter set forth.

What is claimed is:

1. A vaporizer comprising:
a thermally conductive block having a multiplicity of non-moving elongated wells formed therein for placement of a vapor source material, the multiplicity of elongated wells communicatively connected to an interior space within the thermally conductive block for accumulation of vapor;
means for applying heat to the multiplicity of the elongated wells within the thermally conductive block;
means for sealing the thermally conductive block; and
an outlet for discharge of vapor formed in the vaporizer.

2. The vaporizer of claim 1 further comprising a control mechanism for controlling temperature generated by the means for applying heat.

3. The vaporizer of claim 1 containing liquid source material.

4. The vaporizer of claim 1 containing solid source material.

5. The vaporizer of claim 1 containing decaborane

6. The vaporizer of claim 1 wherein at least four elongated wells are formed in the thermally conductive block.

7. The vaporizer of claim 1 wherein the means for applying heat to the thermally conductive block comprise at least one resistive heating element.

8. The vaporizer of claim 1 wherein each wall of the thermally conductive block has at least one resistive heating element attached thereto.

9. The vaporizer of claim 1 wherein the means for controlling temperature comprise a thermocouple.

10. The vaporizer of claim 6 wherein the means for controlling temperature are arranged to maintain the block at a sufficient temperature to vaporize the source material.

11. The vaporizer of claim 1 wherein the thermally conductive block is fabricated of aluminum or an aluminum alloy.

12. The vaporizer of claim 6 wherein the thermally conductive block has an interior volume of about 160 cm³

13. The vaporizer of claim 12 wherein the multiplicity of elongated wells constitute an interior volume of about 60 cm³.

14. The vaporizer of claim 1 wherein the thermally conductive block is uniformly heated, thereby reducing cold spots within the elongated wells and interior space.

15. A method for vaporizing a source material comprising the steps of:
introducing a source material into a multiplicity of elongated wells formed in a thermally conductive block, the multiplicity of elongated wells communicatively connected to an interior space within the thermally conductive block for accumulation of vaporized source material;
sealing the thermally conductive block to form a vacuum in the multiplicity of wells and interior space;
applying heat to the thermally conductive block to simultaneously heat the elongated wells and vaporize source material therein to form source material vapor; and
delivering source material vapor to a deposition system.

16 The method of claim 15 wherein the deposition system comprises a process unit selected from the group consisting of ion implantation units, chemical vapor deposition units, and metal organic chemical vapor deposition units.

17. The method of claim 15 further comprising controlling temperature generated by the step of applying heat.

18. The method of claim 15 wherein the source material is a liquid or a solid.

19. The method of claim 15 wherein the source material comprises decaborane.

20. The method of claim 15 wherein at least four elongated wells are formed within the thermally conductive block.

21. The method of claim 15 wherein the step of applying heat comprises resistively heating the thermally conductive block.

22. The method of claim 15 wherein temperature within the thermally conductive block is maintained at a sufficient temperature to vaporize the source material.

23. The method of claim 15 wherein the thermally conductive block is fabricated of aluminum or aluminum alloy.

24. The method of claim 15 wherein the thermally conductive block is uniformly heated, thereby reducing cold spots within the elongated wells and interior space.

25. A vaporizing and deposition system comprising
a vaporizer comprising: a thermally conductive block having a multiplicity of stationary elongated wells formed therein for placement of a vapor source material, the multiplicity of elongated wells communicatively connected to an interior space within the thermally conductive block for accumulation of vapor;
means for applying heat to the thermally conductive block to vaporize the source material;
means for sealing the thermally conductive block;
an outlet for discharging vaporized source material from the vaporizer; and
a deposition system joined in vapor flow communication with the outlet.

26. The system of claim 25 wherein the source material directly contacts interior surfaces of elongated wells.
